(19) United States
(12) Patent Application Publication
(10) Pub. No.: US 2025/0374766 A1
(43) Pub. Date: Dec. 4, 2025

(54) DISPLAY DEVICE AND METHOD OF MANUFACTURING THE SAME

(71) Applicant: Samsung Display Co., LTD., Yongin-si (KR)

(72) Inventors: Soo Min OH, Yongin-si (KR); Soo Youn KIM, Yongin-si (KR); Woo Yong SUNG, Yongin-si (KR); Hee Jun YANG, Yongin-si (KR); Seung Gun CHAE, Yongin-si (KR)

(21) Appl. No.: 19/053,678

(22) Filed: Feb. 14, 2025

(30) Foreign Application Priority Data
May 31, 2024 (KR) 10-2024-0071762

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes: a substrate including an emission area and a non-emission area; a bank layer on the emission area of the substrate and including a first tip which protrudes in a direction toward the non-emission area; a pixel defining layer on the bank layer and defining an opening; and a light emitting element on the pixel defining layer and including a cathode and an auxiliary electrode, wherein the pixel defining layer comprises a first pixel defining layer and a second pixel defining layer located on the first pixel defining layer and including a second tip which protrudes more than a side surface of the first pixel defining layer toward the non-emission area, and the auxiliary electrode covers the first tip of the bank layer and the second tip of the second pixel defining layer.

### CROSS-REFERENCE TO RELATED APPLICATION

The present application claims priority to and the benefit of Korean Patent Application No. 10-2024-0071762, filed on May 31, 2024, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As the information society develops, consumer demand for display devices for displaying images is increasing in various forms. For example, display devices may be applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display images without a backlight unit that provides light to the display panel.

Recently, display devices have been applied to glasses-type devices for providing virtual reality and augmented reality. In order to be applied to glasses-type devices, a display device may desirably be implemented in a very small size of 2 inches or less, but must have high pixel density to have high resolution. For example, the display device may have a relatively high pixel density (for example, of 1000 pixels per inch (PPI) or more).

If a display device is implemented in a very small size but has a relatively high pixel density as described above, the area of an emission area where a light emitting element is located may be relatively reduced. Therefore, it may be difficult to implement a separate light emitting element in each emission area using a mask process.

The above information disclosed in this Background section is only for enhancement of understanding of the background and therefore the information discussed in this Background section does not necessarily constitute prior art.

### SUMMARY

Aspects of some embodiments of the present disclosure include a display device and a method of manufacturing the same, in which light emitting elements spaced apart from each other are formed without a separate etching process, and a contact area between an auxiliary electrode and a bank structure is relatively increased.

However, aspects of some embodiments according to the present disclosure are not restricted to those specifically set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes a substrate including an emission area and a non-emission area; a bank layer located on the emission area of the substrate and including a first tip which protrudes in a direction toward the non-emission area; a pixel defining layer located on the bank layer and defining an opening; and a light emitting element located on the pixel defining layer and including a cathode and an auxiliary electrode, wherein the pixel defining layer includes a first pixel defining layer and a second pixel defining layer located on the first pixel defining layer and including a second tip which protrudes more than a side surface of the first pixel defining layer toward the non-emission area, and the auxiliary electrode covers the first tip of the bank layer and the second tip of the second pixel defining layer.

According to some embodiments, the side surface of the first pixel defining layer and the second tip of the second pixel defining layer may form an undercut.

According to some embodiments, the first tip may overlap the second tip in a direction perpendicular to the substrate in a portion overlapping the emission area.

According to some embodiments, the first pixel defining layer and the second pixel defining layer may include different materials.

According to some embodiments, a width of the second tip may be 0.01 to 0.5 micrometers in a direction parallel to the substrate.

According to some embodiments, a display device may further include a connection electrode located on the first tip of the bank layer and the second tip of the second pixel defining layer in the direction toward the non-emission area, wherein the connection electrode may do not overlap the opening.

According to some embodiments, the connection electrode may contact and cover the first tip of the bank layer, the side surface of the first pixel defining layer, and the second tip of the second pixel defining layer.

According to some embodiments, the cathode and the auxiliary electrode contact the connection electrode and may be electrically connected to the bank layer by the connection electrode.

According to some embodiments, the bank layer may include a first bank layer, a second bank layer and a third bank layer stacked sequentially, and the second bank layer and the third bank layer may include different materials.

According to some embodiments, the third bank layer comprises the first tip, and an undercut may be formed between a side surface of the second bank layer, which faces the non-emission area, and the first tip of the third bank.

According to some embodiments, the second bank layer may include aluminum, and the third bank layer comprises titanium.

According to some embodiments, a display device may further include a first encapsulation layer located on the light emitting element and including an inorganic material; and a second encapsulation layer located on the first encapsulation layer and including an organic material, wherein the side surface of the second bank layer may include a first portion that contacts the first encapsulation layer and a second portion that contacts the second encapsulation layer.

According to some embodiments, a cavity may be formed between the first bank layer and the first encapsulation layer in the direction perpendicular to the substrate in the portion overlapping the emission area and may be filled with the second encapsulation layer.

According to some embodiments, the auxiliary electrode may contact the first tip of the bank layer, the side surface of the first pixel defining layer, and the second tip of the second pixel defining layer.

According to some embodiments, the light emitting element may further include a light emitting layer located between the second pixel defining layer and the cathode, and the light emitting layer entirely may cover the second pixel defining layer.

According to some embodiments, the bank layer and the pixel defining layer may overlap the emission area and may do not overlap the non-emission area.

According to some embodiments of the present disclosure, a method of manufacturing a display device, the method includes forming a bank layer on an emission area of a substrate and then forming a pixel defining layer and an anode on the bank layer; forming a bank layer including a first tip which protrudes in a direction parallel to the substrate and a pixel defining layer including a second tip which protrudes in a direction parallel to the substrate by removing portions of the bank layer and the pixel defining layer which do not overlap the anode; and forming a light emitting layer on the anode, forming a cathode on the light emitting layer, and forming an auxiliary electrode, which covers the first tip and the second tip, on the cathode, wherein the light emitting layer is formed by a photo pattern process in the forming of the light emitting layer, and the pixel defining layer comprises a first pixel defining layer and a second pixel defining layer including the second tip which protrudes more than a side surface of the first pixel defining layer.

According to some embodiments, in the forming of the first tip, the bank layer may include a first bank layer and a second bank layer having higher etch resistance than the first bank layer.

According to some embodiments, in the forming of the second tip, the second pixel defining layer has higher etch resistance than the first pixel defining layer.

According to some embodiments of the present disclosure, an electronic device includes at least one display device including a substrate which comprises an emission area and a non-emission area; a display device housing in which the at least one display device is housed; and an optical member enlarging a display image of the at least one display device or converting an optical path, wherein the at least one display device includes a bank layer located on the emission area of the substrate and including a first tip which protrudes in a direction toward the non-emission area; a pixel defining layer located on the bank layer and defining an opening; and a light emitting element located on the pixel defining layer and including a cathode and an auxiliary electrode, wherein the pixel defining layer comprises a first pixel defining layer and a second pixel defining layer located on the first pixel defining layer and including a second tip which protrudes more than a side surface of the first pixel defining layer toward the non-emission area, and the auxiliary electrode covers the first tip of the bank layer and the second tip of the second pixel defining layer.

However, aspects of embodiments according to the present disclosure are not limited to those described above and various other characteristics are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a head mounted electronic device according to some embodiments;

FIG. 2 is an exploded perspective view of the head mounted electronic device of FIG. 1;

FIG. 3 is a perspective view of a head mounted electronic device according to some embodiments;

FIG. 4 is an exploded perspective view of a display device according to some embodiments;

FIG. 5 is a schematic cross-sectional view of a display panel according to some embodiments, taken along the line X1-X1′ of FIG. 4;

FIG. 6 is an enlarged cross-sectional view of a light emitting element layer overlapping a first emission area in FIG. 5;

FIG. 7 is an enlarged cross-sectional view of area C in FIG. 6;

FIG. 8 is a schematic cross-sectional view of a display panel according to some embodiments, taken along the line X1-X1′ of FIG. 4;

FIG. 9 is an enlarged cross-sectional view of a light emitting element layer overlapping a first emission area in FIG. 8;

FIG. 10 is a schematic cross-sectional view of a display panel according to some embodiments, taken along the line X1-X1′ of FIG. 4;

FIG. 11 is an enlarged cross-sectional view of a light emitting element layer overlapping a first emission area in FIG. 10; and

FIGS. 12 through 22 are cross-sectional views sequentially illustrating a process of manufacturing a light emitting element layer of a display panel according to some embodiments.

### DETAILED DESCRIPTION

Aspects of some embodiments of the present disclosure will now be described more fully hereinafter with reference to the accompanying drawings, in which embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, aspects of some embodiments will be described in more detail with reference to the accompanying drawings.

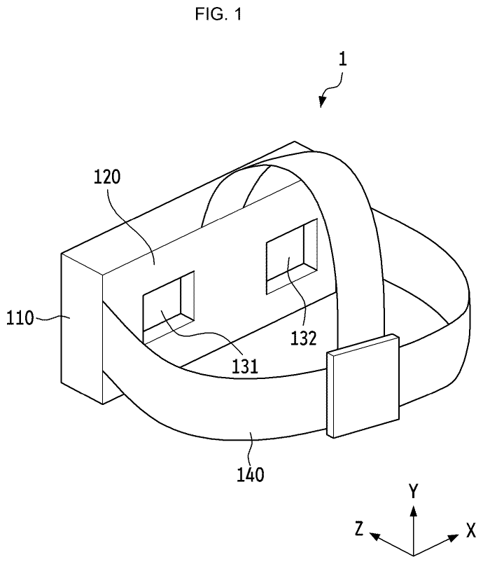

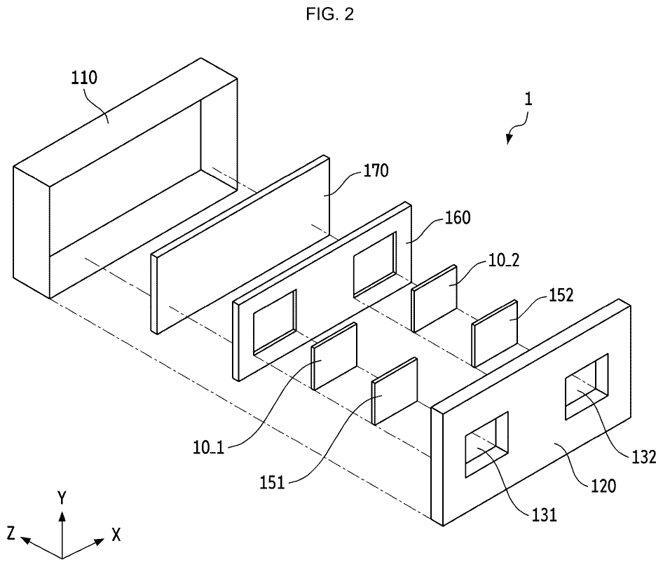

FIG. 1 is a perspective view of a head mounted electronic device 1 according to some embodiments. FIG. 2 is an exploded perspective view of the head mounted electronic device 1 of FIG. 1.

Referring to FIGS. 1 and 2, the head mounted display device 1 according to some embodiments includes display devices 10, a display device housing 110, a housing cover 120, a first eyepiece 131, a second eyepiece 132, a head mounted band 140, a middle frame 160, a first optical member 151, a second optical member 152, and a control circuit board 170.

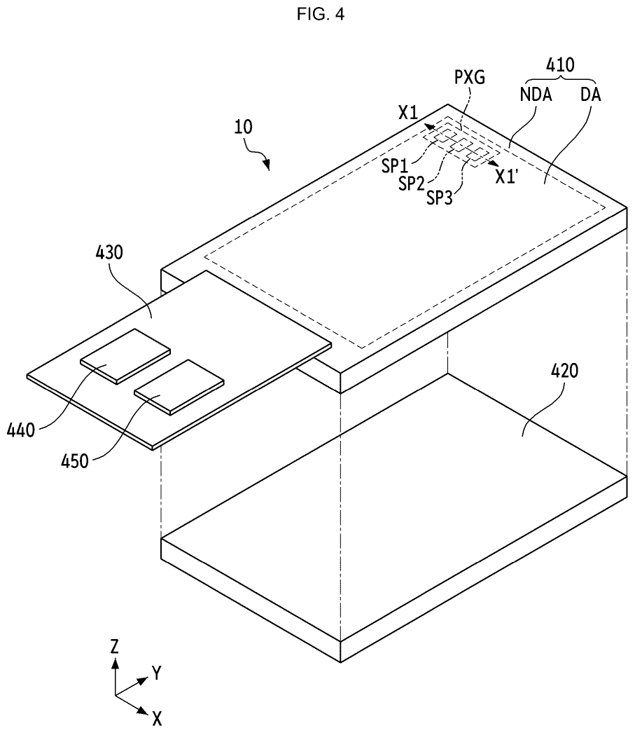

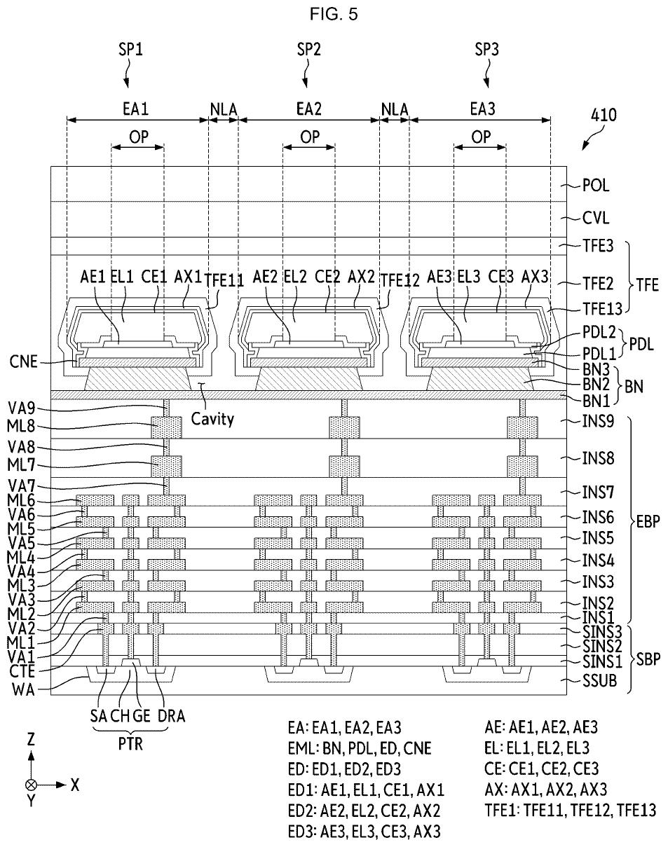

The display devices 10 may include a first display device 10_1 and a second display device 10_2. The first display device 10_1 provides an image to a user's left eye, and the second display device 10_2 provides an image to the user's right eye. The display devices 10 will be described in more detail later with reference to FIGS. 4 and 5.

The first optical member 151 may be located between the first display device 10_1 and the first eyepiece 131. The second optical member 152 may be located between the second display device 10_2 and the second eyepiece 132. Each of the first optical member 151 and the second optical member 152 may include at least one convex lens.

The middle frame 160 may be located between the first display device 10_1 and the control circuit board 170 and may be located between the second display device 10_2 and the control circuit board 170. The middle frame 160 supports and fixes the first display device 10_1, the second display device 10_2, and the control circuit board 170.

The control circuit board 170 may be located between the middle frame 160 and the display device housing 110. The control circuit board 170 may be connected to the first display device 10_1 and the second display device 10_2 through a connector. The control circuit board 170 may convert an image source received from the outside into digital video data and transmit the digital video data to the first display device 10_1 and the second display device 10_2 through the connector.

The control circuit board 170 may transmit digital video data corresponding to a left image optimized for a user's left eye to the first display device 10_1 and transmit digital video data corresponding to a right image optimized for the user's right eye to the second display device 10_2. Alternatively, the control circuit board 170 may transmit the same digital video data to the first display device 10_1 and the second display device 10_2.

The display device housing 110 houses the display devices 10, the middle frame 160, the first optical member 151, the second optical member 152, and the control circuit board 170. The housing cover 120 is placed to cover an open surface of the display device housing 110. The housing cover 120 may include the first eyepiece 131 on which a user's left eye is placed and the second eyepiece 132 on which the user's right eye is placed. Although the first eyepiece 131 and the second eyepiece 132 are arranged separately in FIGS. 1 and 2, embodiments of the present disclosure are not limited thereto. The first eyepiece 131 and the second eyepiece 132 may also be combined into one.

The first eyepiece 131 may be aligned with the first display device 10_1 and the first optical member 151, and the second eyepiece 132 may be aligned with the second display device 10_2 and the second optical member 152. Therefore, a user can view an image of the first display device 10_1, which is enlarged as a virtual image by the first optical member 151, through the first eyepiece 131 and can view an image of the second display device 10_2, which is enlarged as a virtual image by the second optical member 152, through the second eyepiece 132.

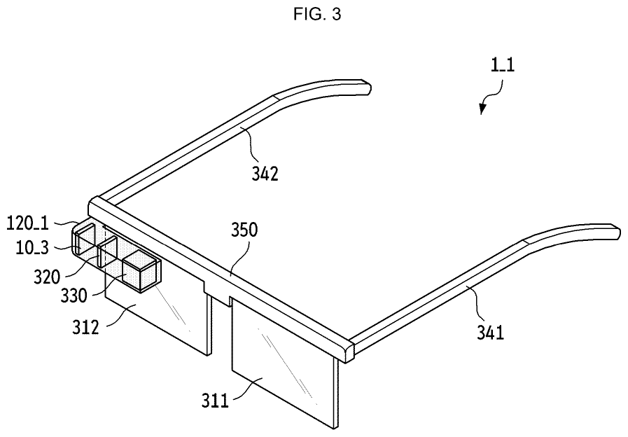

The head mounted band 140 fixes the display device housing 110 to a user's head so that the first eyepiece 131 and the second eyepiece 132 of the housing cover 120 are kept placed on the user's left and right eyes, respectively. When the display device housing 110 is implemented to be lightweight and small, the head mounted electronic device 1 may include an eyeglass frame as illustrated in FIG. 3 instead of the head mounted band 140.

In addition, the head mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view of a head mounted electronic device 1_1 according to some embodiments.

Referring to FIG. 3, the head mounted electronic device 1_1 according to some embodiments may be an electronic device in the form of glasses in which a display device housing 120_1 is implemented to be lightweight and small. The head mounted electronic device 1_1 according to some embodiments may include a display device 10, a left lens 311, a right lens 312, a support frame 350, eyeglass frame legs 341 and 342, an optical member 320, an optical path conversion member 330, and the display device housing 120_1.

The display device 10 illustrated in FIG. 3 may include a third display device 10_3. The third display device 10_3 may be substantially the same as the first display device 10_1 and the second display device 10_2 illustrated in FIG. 2. The display device 10 will be described later with reference to FIGS. 4 and 5.

The display device housing 120_1 may include the display device 10, the optical member 320, and the optical path conversion member 330. Images displayed on the display device 10 may be enlarged by the optical member 320, may have its optical path converted by the optical path conversion member 330, and then may be provided to a user's right eye through the right lens 312. Accordingly, the user can view, through the right eye, an augmented reality image into which a virtual image displayed on the display device 10 and a real image viewed through the right lens 312 are combined.

Although the display device housing 120_1 is located at a right end of the support frame 350 in FIG. 3, embodiments of the present disclosure are not limited thereto. For example, the display device housing 120_1 may also be located at a left end of the support frame 350. In this case, an image of the display device 10 may be provided to a user's left eye. Alternatively, the display device housing 120_1 may be located at both the left and right ends of the support frame 350. In this case, the user can view an image displayed on the display device 10 through both the left and right eyes.

FIG. 4 is an exploded perspective view of a display device 10 according to some embodiments.

Referring to FIG. 4, the display device 10 according to some embodiments is a device for displaying moving images (e.g., video images) or still images (e.g., static images). The display device 10 according to some embodiments may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 according to some embodiments may be applied as a display unit of a television, a notebook computer, a monitor, a billboard, or an Internet of things (IoT) device. Alternatively, the display device 10 according to some embodiments may be applied to smart watches, watch phones, and head mounted displays for implementing virtual reality and augmented reality.

The display device 10 according to some embodiments includes a display panel 410, a heat dissipation layer 420, a circuit board 430, a driving circuit 440, and a power supply circuit 450.

The display panel 410 may have a planar shape similar to a quadrangle. For example, the display panel 410 may have a planar shape similar to a quadrangle having short sides in a first direction X and long sides in a second direction Y intersecting the first direction X. In the display panel 410, each corner where a short side extending in the first direction X meets a long side extending in the second direction Y may be rounded to have a curvature (e.g., a set or predetermined curvature) or may be right-angled. The planar shape of the display panel 410 is not limited to a quadrangular shape and may also be similar to other polygonal shapes, a circular shape, or an oval shape. The planar shape of the display device 10 may follow the planar shape of the display panel 410, but embodiments of the present disclosure are not limited thereto.

A display area DA may be located in the center of the display panel 410 and may occupy most of the area of the display panel 410. The display area DA may include pixel groups PXG, and each of the pixel groups PXG may be a smallest unit that emits white light. Each of the pixel groups PXG may include first through third pixels SP1 through SP3. The first through third pixels SP1 through SP3 may emit light of the same color or may emit light of different colors. A non-display area NDA may surround edges of the display area DA.

The heat dissipation layer 420 may overlap the display panel 410 in a third direction Z which is a thickness direction of the display panel 410. The heat dissipation layer 420 may be located on a surface, e.g., a back surface of the display panel 410. The heat dissipation layer 420 dissipates heat generated from the display panel 410. The heat dissipation layer 420 may include a metal layer or thermally conductive layer having high thermal conductivity, such as graphite, silver (Ag), copper (Cu), or aluminum (Al).

The circuit board 430 may be positioned on the non-display area NDA of the display panel 410 by using a conductive adhesive member such as an anisotropic conductive film. The circuit board 430 may be a flexible printed circuit board made of a flexible material or may be a flexible film. Although the circuit board 430 is unfolded in FIG. 4, it may also be bent. In this case, one end of the circuit board 430 may be placed on the back surface of the display panel 410. The end of the circuit board 300 may be an end opposite the other end of the circuit board 430 which is connected to a plurality of pads in a pad area of the display panel 100 by using a conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to a power supply voltage received from the outside. For example, the power supply circuit 450 may generate a first driving voltage (e.g., VSS), a second driving voltage (e.g., VDD) and a third driving voltage (e.g., VINT) and supply them to the display panel 410.

Each of the driving circuit 440 and the power supply circuit 450 may be formed as an integrated circuit and attached to a surface of the circuit board 430.

FIG. 5 is a schematic cross-sectional view of a display panel 410 according to some embodiments, taken along the line X1-X1′ of FIG. 4.

Referring to FIG. 5, the display panel 410 includes a semiconductor backplane SBP, a light emitting element backplane EBP, a light emitting element layer EML, an encapsulation layer TFE, a cover layer CVL, and a polarizer POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR.

The semiconductor substrate SSUB may be a silicon substrate, a germanium substrate, or a silicon-germanium substrate. The semiconductor substrate SSUB may be a substrate doped with a first-type impurity. A plurality of well areas WA may be located in an upper surface of the semiconductor substrate SSUB. The well areas WA may be areas doped with a second-type impurity. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

The semiconductor substrate SSUB can be replaced with a glass substrate or a polymer resin substrate such as polyimide. In this case, thin-film transistors may be located on the glass substrate or the polymer resin substrate. The glass substrate may be a rigid substrate that is not bent, and the polymer resin substrate may be a flexible substrate that can be bent or curved.

Each of the well areas WA includes a source area SA corresponding to a source electrode of a pixel transistor PTR, a drain area DRA corresponding to a drain electrode of the pixel transistor PTR, and a channel area CH located between the source area SA and the drain area DRA.

Each of the source area SA and the drain area DRA may be an area doped with the first-type impurity. A gate electrode GE of each pixel transistor PTR may overlap a well area WA in the third direction (Z-axis direction). The channel area CH may overlap the gate electrode GE in the third direction (Z-axis direction). The source area SA may be located on one side of the gate electrode GE, and the drain area DRA may be located on the other side of the gate electrode GE.

A first semiconductor insulating layer SINS1 may be located on the semiconductor substrate SSUB. The first semiconductor insulating layer SINS1 may be a silicon carbon nitride (SiCN) or silicon oxide (SiOx)-based inorganic layer, but embodiments of the present disclosure are not limited thereto.

A second semiconductor insulating layer SINS2 may be located on the first semiconductor insulating layer SINS1. The second semiconductor insulating layer SINS2 may be a silicon oxide (SiOx)-based inorganic layer, but embodiments of the present disclosure are not limited thereto.

The contact terminals CTE may be located on the second semiconductor insulating layer SINS2. Each of the contact terminals CTE may be connected to any one of the gate electrode GE, the source area SA, and the drain area DRA of a pixel transistor PTR through a hole penetrating the first semiconductor insulating layer SINS1 and the second semiconductor insulating layer SINS2. The contact terminals CTE may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may be a silicon oxide (SiOx)-based inorganic layer, but embodiments of the present disclosure are not limited thereto.

The light emitting element backplane EBP includes first through eighth metal layers ML1 through ML8, and a plurality of vias VA1 through VA9. In addition, the light emitting element backplane EBP includes first through ninth interlayer insulating layers INS1 through INS9 located between the first through eighth metal layers ML1 through ML8.

The first through eighth metal layers ML1 through ML8 implement a circuit of a subpixel SP by connecting the contact terminals CTE exposed in the semiconductor backplane SBP.

The first interlayer insulating layer INS1 may be located on the semiconductor backplane SBP. Each of first vias VA1 may penetrate the first interlayer insulating layer INS1 and may be connected to a contact terminal CTE exposed in the semiconductor backplane SBP. Each of the first metal layers ML1 may be located on the first interlayer insulating layer INS1 and may be connected to a first via VA1.

The second interlayer insulating layer INS2 may be located on the first interlayer insulating layer INS1 and the first metal layers ML1. Each of second vias VA2 may penetrate the second interlayer insulating layer INS2 and may be connected to an exposed first metal layer ML1. Each of the second metal layers ML2 may be located on the second interlayer insulating layer INS2 and may be connected to a second via VA2.

The third interlayer insulating layer INS3 may be located on the second interlayer insulating layer INS2 and the second metal layers ML2. Each of third vias VA3 may penetrate the third interlayer insulating layer INS3 and may be connected to an exposed second metal layer ML2. Each of the third metal layers ML3 may be located on the third interlayer insulating layer INS3 and may be connected to a third via VA3.

The fourth interlayer insulating layer INS4 may be located on the third interlayer insulating layer INS3 and the third metal layers ML3. Each of fourth vias VA4 may penetrate the fourth interlayer insulating layer INS4 and may be connected to an exposed third metal layer ML3. Each of the fourth metal layers ML4 may be located on the fourth interlayer insulating layer INS4 and may be connected to a fourth via VA4.

The fifth interlayer insulating layer INS5 may be located on the fourth interlayer insulating layer INS4 and the fourth metal layers ML4. Each of fifth vias VA5 may penetrate the fifth interlayer insulating layer INS5 and may be connected to an exposed fourth metal layer ML4. Each of the fifth metal layers ML5 may be located on the fifth interlayer insulating layer INS5 and may be connected to a fifth via VA5.

The sixth interlayer insulating layer INS6 may be located on the fifth interlayer insulating layer INS5 and the fifth metal layers ML5. Each of sixth vias VA6 may penetrate the sixth interlayer insulating layer INS6 and may be connected to an exposed fifth metal layer ML5. Each of the sixth metal layers ML6 may be located on the sixth interlayer insulating layer INS6 and may be connected to a sixth via VA6.

The seventh interlayer insulating layer INS7 may be located on the sixth interlayer insulating layer INS6 and the sixth metal layers ML6. Each of seventh vias VA7 may penetrate the seventh interlayer insulating layer INS7 and may be connected to an exposed sixth metal layer ML6. Each of the seventh metal layers ML7 may be located on the seventh interlayer insulating layer INS7 and may be connected to a seventh via VA7.

The eighth interlayer insulating layer INS8 may be located on the seventh interlayer insulating layer INS7 and the seventh metal layers ML7. Each of eighth vias VA8 may penetrate the eighth interlayer insulating layer INS8 and may be connected to an exposed seventh metal layer ML7. Each of the eighth metal layers ML8 may be located on the eighth interlayer insulating layer INS8 and may be connected to an eighth via VA8.

The first through eighth metal layers ML1 through ML8 and the first through eighth vias VA1 through VA8 may be made of substantially the same material. The first through eighth metal layers ML1 through ML8 and the first through eighth vias VA1 through VA8 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same. The first through eighth vias VA1 through VA8 may be made of substantially the same material. Each of the first through eighth interlayer insulating layers INS1 through INS8 may be a silicon oxide (SiOx)-based inorganic layer, but embodiments of the present disclosure are not limited thereto.

A thickness of the first metal layers ML1, a thickness of the second metal layers ML2, a thickness of the third metal layers ML3, a thickness of the fourth metal layers ML4, a thickness of the fifth metal layers ML5, and a thickness of the sixth metal layers ML6 may be greater than a thickness of the first vias VA1, a thickness of the second vias VA2, a thickness of the third vias VA3, a thickness of the fourth vias VA4, a thickness of the fifth vias VA5, and a thickness of the sixth vias VA6, respectively. The thickness of the second metal layers ML2, the thickness of the third metal layers ML3, the thickness of the fourth metal layers ML4, the thickness of the fifth metal layers ML5, and the thickness of the sixth metal layers ML6 may each be greater than the thickness of the first metal layers ML1. The thickness of the second metal layers ML2, the thickness of the third metal layers ML3, the thickness of the fourth metal layers ML4, the thickness of the fifth metal layers ML5, and the thickness of the sixth metal layers ML6 may be substantially the same.

A thickness of the seventh metal layers ML7 and a thickness of the eighth metal layers ML8 may each be greater than each of the thickness of the first metal layers ML1, the thickness of the second metal layers ML2, the thickness of the third metal layers ML3, the thickness of the fourth metal layers ML4, the thickness of the fifth metal layers ML5, and the thickness of the sixth metal layer ML6. The thickness of the seventh metal layers ML7 and the thickness of the eighth metal layers ML8 may be greater than a thickness of the seventh vias VA7 and a thickness of the eighth vias VA8, respectively. The thickness of the seventh vias VA7 and the thickness of the eighth vias VA8 may each be greater than each of the thickness of the first vias VA1, the thickness of the second vias VA2, the thickness of the third vias VA3, the thickness of the fourth vias VA4, the thickness of the fifth vias VA5, and the thickness of the sixth vias VA6. The thickness of the seventh metal layers ML7 and the thickness of the eighth metal layers ML8 may be substantially the same.

The ninth interlayer insulating layer INS9 may be located on the eighth interlayer insulating layer INS8 and the eighth metal layers ML8. The ninth interlayer insulating layer INS9 may be a silicon oxide (SiOx)-based inorganic layer, but embodiments of the present disclosure are not limited thereto.

Each of ninth vias VA9 may penetrate the ninth interlayer insulating layer INS9 and may be connected to an exposed eighth metal layer ML8. The ninth vias VA9 may be made of any one of copper (Cu), aluminum (Al), tungsten (W), molybdenum (Mo), chromium (Cr), gold (Au), titanium (Ti), nickel (Ni) and neodymium (Nd) or may be made of an alloy including any one of the same.

The light emitting element layer EML may be located on the light emitting element backplane EBP. The light emitting element layer EML may include a bank layer BN, a pixel defining layer PDL, light emitting elements ED, and connection electrodes CNE.

The bank layer BN according to some embodiments may be located on the ninth interlayer insulating layer INS9 in portions overlapping emission areas EA. The bank layer BN may not overlap a non-emission area NLA.

The bank layer BN may include a first bank layer BN1, a second bank layer BN2, and a third bank layer BN3. The first bank layer BN1, the second bank layer BN2, and the third bank layer BN3 may be sequentially stacked in the third direction (Z-axis direction).

The first bank layer BN1 according to some embodiments may be located on the ninth interlayer insulating layer INS9. The first bank layer BN1 may cover the entire surface of the ninth interlayer insulating layer INS9. The first bank layer BN1 may be connected to the eighth metal layers ML8 through the ninth vias VA9.

The first bank layer BN1 may include a conductive metal having etch resistance. For example, the first bank layer BN1 may be titanium (Ti).

The second bank layer BN2 according to some embodiments may be located on the first bank layer BN1. The second bank layer BN2 may be electrically connected to the first bank layer BN1. In other words, the second bank layer BN2 may be connected to the ninth vias VA9 through the first bank layer BN1.

The second bank layer BN2 may include a metal having high electrical conductivity. For example, the second bank layer BN2 may include aluminum (Al).

The third bank layer BN3 according to some embodiments may be located on the second bank layer BN2. The third bank layer BN3 may be electrically connected to the second bank layer BN2. That is, the third bank layer BN3 may be connected to the ninth vias VA9 through the first bank layer BN1 and the second bank layer BN2.

The third bank layer BN3 may include a conductive metal having etch resistance. For example, the third bank layers BN3 may be titanium (Ti).

In a process of manufacturing the display panel 410, the third bank layer BN3 may have a lower etch rate than the second bank layer BN2. Therefore, the third bank layer BN3 may have a portion protruding more than the second bank layer BN2 in the first direction (X-axis direction). This will be described in more detail later.

The pixel defining layer PDL according to some embodiments may be located on the bank layer BN in the portions overlapping the emission areas EA. The pixel defining layer PDL may not overlap the non-emission area NLA.

The pixel defining layer PDL may include a first pixel defining layer PDL1 and a second pixel defining layer PDL2 stacked sequentially. The first pixel defining layer PDL1 and the second pixel defining layer PDL2 may be sequentially stacked in the third direction (Z-axis direction).

The first pixel defining layer PDL1 according to some embodiments may be located on the third bank layer BN3. The first pixel defining layer PDL1 may insulate the bank layer BN from anodes AE.

The first pixel defining layer PDL1 may include an inorganic insulating material. For example, the first pixel defining layer PDL1 may include at least one of silicon nitride, silicon oxide, or silicon oxynitride.

The second pixel defining layer PDL2 may be located on the first pixel defining layer PDL1 and the anodes AE. The second pixel defining layer PDL2 may expose openings OP and cover edges of the anodes AE.

The second pixel defining layer PDL2 may include an inorganic insulating material. For example, the second pixel defining layer PDL2 may include at least one of silicon nitride, silicon oxide, or silicon oxynitride.

However, the second pixel defining layer PDL2 may include a different material from the first pixel defining layer PDL1. For example, when the first pixel defining layer PDL1 is silicon nitride, the second pixel defining layer PDL2 may be silicon oxide.

The second pixel defining layer PDL2 may have a protruding portion which protrudes more than the first pixel defining layer PDL1 toward the non-emission area NLA in the first direction (X-axis direction). In other words, the pixel defining layer PDL may have a step. This will be described in more detail later.

The light emitting elements ED according to some embodiments may be located on the pixel defining layer PDL. The light emitting elements ED may include a first light emitting element ED1 located in a first emission area EA1, a second light emitting element ED2 located in a second emission area EA2, and a third light emitting element ED3 located in a third emission area EA3. The first light emitting element ED1, the second light emitting element ED2, and the third light emitting element ED3 may be spaced apart from each other.

The first light emitting element ED1 may include a first anode AE1, a first light emitting layer EL1, a first cathode CE1, and a first auxiliary electrode AX1. The second light emitting element ED2 may include a second anode AE2, a second light emitting layer EL2, a second cathode CE2, and a second auxiliary electrode AX2. The third light emitting element ED3 may include a third anode AE3, a third light emitting layer EL3, a third cathode CE3, and a third auxiliary electrode AX3.

The first light emitting element ED1, the second light emitting element ED2, and the third light emitting element ED3 may emit light of different colors. For example, the first light emitting element ED1 may emit red light, the second light emitting element ED2 may emit green light, and the third light emitting element ED3 may emit blue light.

The anodes AE according to some embodiments may be located on the first pixel defining layer PDL1. The anodes AE may include the first anode AE1, the second anode AE2, and the third anode AE3. The first anode AE1 may be located in a portion overlapping the first emission area EA1, the second anode AE2 may be located in a portion overlapping the second emission area EA2, and the third anode AE3 may be located in a portion overlapping the third emission area EA3.

The anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anodes AE may have, but are not limited to, a multilayer structure of ITO/Mg, ITO/MgF, ITO/Ag, or ITO/Ag/ITO.

Light emitting layers EL according to some embodiments may be located on the anodes AE. The light emitting layers EL may be organic light emitting layers made of an organic material and may be formed on the anodes AE through a deposition process. The light emitting layers EL may contact the anodes AE in portions overlapping the openings OP and may entirely cover the second pixel defining layer PDL2.

The light emitting layers EL may include the first light emitting layer EL1, the second light emitting layer EL2, and the third light emitting layer EL3. The first light emitting layer EL1 may be located in the portion overlapping the first emission area EA1, the second light emitting layer EL2 may be located in the portion overlapping the second emission area EA2, and the third light emitting layer EL3 may be located in the portion overlapping the third emission area EA3.

The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light. However, embodiments according to the present disclosure are not limited thereto.

In the display panel 410 according to some embodiments, because the pixel defining layer PDL includes a step, the first through third light emitting layers EL1 through EL3 spaced apart from each other can be formed without using a fine metal mask. In other words, in a process of forming the light emitting layers EL during the process of manufacturing the display panel 410, because the pixel defining layer PDL includes a step, a deposition area of a material that forms the light emitting layers EL can be controlled without using a fine metal mask. The manufacturing process will be described later.

Cathodes CE according to some embodiments may be located on the light emitting layers EL. The cathodes CE may entirely cover the light emitting layers EL.

The cathodes CE may include a transparent conductive material to transmit light generated from the light emitting layers EL. For example, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The cathodes CE may further include a transparent metal oxide layer located on the material layer having a small work function.

The cathodes CE may include the first cathode CE1, the second cathode CE2, and the third cathode CE3. The first cathode CE1 may be located in the portion overlapping the first emission area EA1, the second cathode CE2 may be located in the portion overlapping the second emission area EA2, and the third cathode CE3 may be located in the portion overlapping the third emission area EA3.

The first cathode CE1, the second cathode CE2, and the third cathode CE3 may be spaced apart from each other. The first cathode CE1, the second cathode CE2, and the third cathode CE3 may not be directly connected but may be electrically connected through auxiliary electrodes AX and the bank layer BN.

In the display panel 410 according to some embodiments, because the pixel defining layer PDL includes a step, the first through third cathodes CE1 through CE3 spaced apart from each other can be formed without using a fine metal mask. In other words, in a process of forming the cathodes CE during the process of manufacturing the display panel 410, because the pixel defining layer PDL includes a step, a deposition area of a material that forms the cathodes CE can be controlled without using a fine metal mask. The manufacturing process will be described later.

The auxiliary electrodes AX according to some embodiments may be located on the cathodes CE. The auxiliary electrodes AX may entirely cover the cathodes CE.

The auxiliary electrodes AX may include a transparent conductive material (TCO). For example, the auxiliary electrodes AX may include indium-zinc-oxide (IZO).

The auxiliary electrodes AX may include the first auxiliary electrode AX1, the second auxiliary electrode AX2, and the third auxiliary electrode AX3. The first auxiliary electrode AX1 may be located in the portion overlapping the first emission area EA1, the second auxiliary electrode AX2 may be located in the portion overlapping the second emission area EA2, and the third auxiliary electrode AX3 may be located in the portion overlapping the third emission area EA3.

The first auxiliary electrode AX1, the second auxiliary electrode AX2, and the third auxiliary electrode AX3 may be spaced apart from each other. The first auxiliary electrode AX1, the second auxiliary electrode AX2, and the third auxiliary electrode AX3 may not be directly connected but may be electrically connected through the bank layer BN.

In the display panel 410 according to some embodiments, because the pixel defining layer PDL includes a step, the first through third auxiliary electrodes AX1 through AX3 spaced apart from each other can be formed without using a fine metal mask. In other words, in a process of forming the auxiliary electrodes AX during the process of manufacturing the display panel 410, because the pixel defining layer PDL includes a step, a deposition area of a material that forms the auxiliary electrodes AX can be controlled without using a fine metal mask. The manufacturing process will be described later.

The connection electrodes CNE according to some embodiments may be located on the pixel defining layer PDL and the third bank layer BN3 in a direction toward the non-emission area NLA. The connection electrodes CNE may be located on side surfaces of the pixel defining layer PDL and side surfaces of the third bank layer BN3 in the direction toward the non-emission area NLA.

Generally, if a contact failure occurs between a cathode CE, an auxiliary electrode AX and the bank layer BN, the display panel 410 may suffer from reliability problems such as poor luminance and reduced efficiency. To solve this, the display panel 410 according to some embodiments may use the connection electrodes CNE to relatively increase a contact area between the auxiliary electrodes AX and the bank layer BN. Therefore, the contact failure between the auxiliary electrodes AX and the bank layer BN can be solved. This will be described in more detail later.

The connection electrodes CNE may include a transparent conductive material (TCO). For example, the connection electrodes CNE may include indium-zinc-oxide (IZO).

The encapsulation layer TFE according to some embodiments may be located on the light emitting element layer EML. The encapsulation layer TFE may include at least one inorganic layer and one organic layer to prevent or reduce instances of contaminants such as oxygen or moisture penetrating into the light emitting element layer EML.

The encapsulation layer TFE may include a first encapsulation layer TFE1, a second encapsulation layer TFE2, and a third encapsulation layer TFE3. The first encapsulation layer TFE1, the second encapsulation layer TFE2, and the third encapsulation layer TFE3 may be sequentially stacked in the third direction (Z-axis direction).

The first encapsulation layer TFE1 according to some embodiments may be located on the light emitting elements ED. The first encapsulation layer TFE1 may cover the bank layer BN and the light emitting elements ED. The first encapsulation layer TFE1 may be formed with a uniform thickness along the profiles of structures thereunder and thus may include a step.

The first encapsulation layer TFE1 may include an inorganic insulating material. For example, the first encapsulation layer TFE1 may include any one of silicon oxide, silicon nitride, and silicon oxynitride.

Cavities Cavity may be formed between the first encapsulation layer TFE1 and the first bank layer BN1 in portions adjacent to the second bank layer BN2. In other words, the first encapsulation layer TFE1 may be spaced apart from the first bank layer BN1 in the third direction (Z-axis direction). The cavities Cavity may be portions where the material that forms the light emitting layers EL, the material that forms the cathodes CE, and the material that forms the auxiliary electrodes AX were located and then removed during the process of manufacturing the display panel 410. The manufacturing process will be described later.

The first encapsulation layer TFE1 may include a first inorganic layer TFE11, a second inorganic layer TFE12, and a third inorganic layer TFE13. The first inorganic layer TFE11 may be located in the portion overlapping the first emission area EA1, the second inorganic layer TFE12 may be located in the portion overlapping the second emission area EA2, and the third inorganic layer TFE13 may be located in the portion overlapping the third emission area EA3.

The first inorganic layer TFE11, the second inorganic layer TFE12, and the third inorganic layer TFE13 may be spaced apart from each other. Although the first inorganic layer TFE11, the second inorganic layer TFE12, and the third inorganic layer TFE13 are formed on the same layer in the drawing, they may be formed in different processes. For example, the first inorganic layer TFE11 may be formed after the first light emitting element ED1 is formed, the second inorganic layer TFE12 may be formed after the second light emitting element ED2 is formed, and the third inorganic layer TFE13 may be formed after the third light emitting element ED3 is formed. The manufacturing process will be described later.

The second encapsulation layer TFE2 according to some embodiments may be located on the first encapsulation layer TFE1. The second encapsulation layer TFE2 may flatten steps formed by the first encapsulation layer TFE1 in portions overlapping the emission areas EA and the non-emission area NLA. The second encapsulation layer TFE2 may also fill the cavities Cavity located between the first encapsulation layer TFE1 and the first bank layer BN1.

The second encapsulation layer TFE2 may include a polymer-based material. For example, the second encapsulation layer TFE2 may include acrylic resin, silicone resin, silicone acrylic resin, epoxy resin, etc. The second encapsulation layer TFE2 may be formed by curing a monomer or applying a polymer.

The third encapsulation layer TFE3 according to some embodiments may be located on the second encapsulation layer TFE2 and may completely cover the second encapsulation layer TFE2. The third encapsulation layer TFE3 may include the same material as the first encapsulation layer TFE1. Depending on embodiments, the third encapsulation layer TFE3 can be omitted.

The cover layer CVL may be located on the encapsulation layer TFE. The cover layer CVL may be a glass substrate or a polymer resin such as resin. When the cover layer CVL is a glass substrate, it may function as an encapsulation substrate. When the cover layer CVL is a polymer resin such as resin, an adhesive layer may be added between the cover layer CVL and the encapsulation layer TFE.

The polarizer POL may be located on the cover layer CVL. The polarizer POL may be a structure for preventing or reducing visibility reduction due to the reflection of external light. The polarizer POL may include a linear polarizer and a phase retardation film. For example, the phase retardation film may be a quarter-wave plate (λ/4 plate), but embodiments of the present disclosure are not limited thereto.

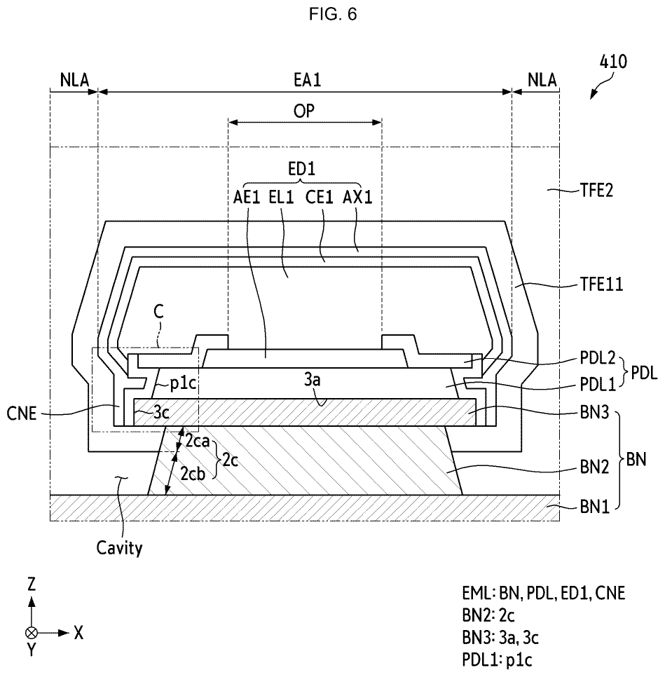

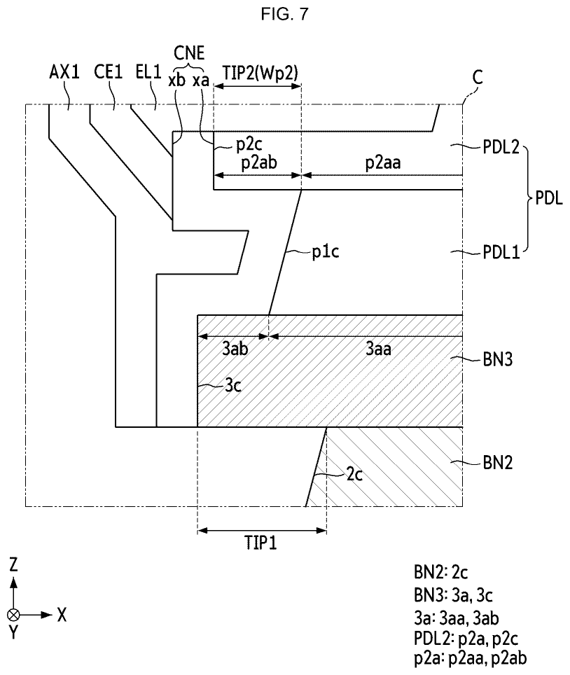

FIG. 6 is an enlarged cross-sectional view of the light emitting element layer EML overlapping the first emission area EA1 in FIG. 5. FIG. 7 is an enlarged cross-sectional view of area C in FIG. 6.

Referring to FIGS. 6 and 7, the light emitting element layer EML may include the bank layer BN, the pixel defining layer PDL, the first light emitting element ED1, and a connection electrode CNE in the portion overlapping the first emission area EA1.

The second bank layer BN2 according to some embodiments may be located on and in contact with the first bank layer BN1 in the portion overlapping the first emission area EA1. The second bank layer BN2 may include side surfaces 2c. The side surfaces 2c of the second bank layer BN2 may be surfaces that face the non-emission area NLA.

According to some embodiments, each of the side surfaces 2c of the second bank layer BN2 may be divided into a first portion 2ca and a second portion 2cb depending on a portion that it contacts. The first portion 2ca may be a portion that contacts the first inorganic layer TFE11, and the second portion 2cb may be a portion that contacts the second encapsulation layer TFE2.

The third bank layer BN3 according to some embodiments may be located on and in contact with the second bank layer BN2 in the portion overlapping the first emission area EA1. The third bank layer BN3 may include an upper surface 3a and side surfaces 3c. The upper surface 3a of the third bank layer BN3 may be a surface that faces the first pixel defining layer PDL1, and the side surfaces 3c of the third bank layer BN3 may be surfaces that face the non-emission area NLA. The upper surface 3a and the side surface 3c of the third bank layer BN3 may be connected.

The side surfaces 3c of the third bank layer BN3 may protrude more than the side surfaces 2c of the second bank layer BN2 toward the non-emission area NLA. In other words, the third bank layer BN3 may have first tips TIP1 that protrude more than the side surfaces 2c of the second bank layer BN2 toward the non-emission area NLA. Accordingly, an undercut may be formed between the first tips TIP1 of the third bank layer BN3 and the side surfaces 2c of the second bank layer BN2.

The first tips TIP1 of the third bank layer BN3 may be formed because the second bank layer BN2 and the third bank layer BN3 include different etch rates in the manufacturing process. The manufacturing process will be described later.

In some embodiments, the upper surface 3a of the third bank layer BN3 may include a first portion 3aa and a second portion 3ab depending on a structure that it contacts. The first portion 3aa may be a portion that contacts the first pixel defining layer PDL1, and the second portion 3ab may be a portion that contacts the connection electrode CNE.

The first pixel defining layer PDL1 according to some embodiments may be located on and in contact with the third bank layer BN3 in the portion overlapping the first emission area EA1. The first pixel defining layer PDL1 may include side surfaces plc that face the non-emission area NLA. The side surfaces pic of the first pixel defining layer PDL1 may be recessed more than the side surfaces 3c of the third bank layer BN3 in a direction toward an opening OP. In other words, a step may be formed between the side surfaces pic of the first pixel defining layer PDL1 and the third bank layer BN3.

The second pixel defining layer PDL2 according to some embodiments may be located on and in contact with an anode AE and the first pixel defining layer PDL1 in the portion overlapping the first emission area EA1. The second pixel defining layer PDL2 may surround the opening OP and expose the first anode AE1.

The second pixel defining layer PDL2 may include a lower surface p2a and side surfaces p2c. The lower surface p2a of the second pixel defining layer PDL2 may be a surface that faces the first pixel defining layer PDL1, and the side surfaces p2c of the second pixel defining layer PDL2 may be surfaces that face the non-emission area NLA. The lower surface p2a and the side surfaces p2c of the second pixel defining layer PDL2 may be connected to each other.

The side surfaces p2c of the second pixel defining layer PDL2 may protrude more than the side surfaces pic of the first pixel defining layer PDL1 toward the non-emission area NLA. In other words, the second pixel defining layer PDL2 may have second tips TIP2 that protrude more than the side surfaces p1c of the first pixel defining layer PDL1 toward the non-emission area NLA. Accordingly, an undercut may be formed between the second tips TIP2 of the second pixel defining layer PDL2 and the side surfaces p1c of the first pixel defining layer PDL1.

The second tips TIP2 of the second pixel defining layer PDL2 may be formed because the first pixel defining layer PDL1 and the second pixel defining layer PDL2 include different etch rates for the same etching process in the manufacturing process. The manufacturing process will be described later.

The first tips TIP1 of the first pixel defining layer PDL1 and the second tips TIP2 of the second pixel defining layer PDL2 may overlap in the third direction (Z-axis direction) in the portion overlapping the first emission area EA1.

In some embodiments, a width Wp2 of the second tips TIP2 of the second pixel defining layer PDL2 may have a value of 0.01 to 0.5 micrometers.

In some embodiments, the lower surface p2a of the second pixel defining layer PDL2 may include a first portion p2aa and a second portion p2ab depending on a structure that it contacts. The first portion p2aa may be a portion that contacts the first pixel defining layer PDL1, and the second portion p2ab may be a portion that contacts the connection electrode CNE.

The connection electrode CNE according to some embodiments may be located in the direction toward the non-emission area NLA to contact the third bank layer BN3, the first pixel defining layer PDL1, and the second pixel defining layer PDL2. The connection electrode CNE may cover them along a profile formed by the first tips TIP1 of the third bank layer BN3 and the side surfaces p1c of the first pixel defining layer PDL1 and a profile formed by the second tips TIP2 of the second pixel defining layer PDL2 and the side surfaces p1c of the first pixel defining layer PDL1. Therefore, the connection electrode CNE may have a large contact area with the third bank layer BN3 and the pixel defining layer PDL.

In some embodiments, the connection electrode CNE may include a first surface xa and a second surface xb. The first surface xa of the connection electrode CNE may cover the upper surface 3a and the side surfaces 3c of the third bank layer BN3 and may contact the upper surface 3a and the side surfaces 3c. In addition, the first surface xa may cover the entire side surfaces p1c of the first pixel defining layer PDL1 and may contact the entire side surfaces p1c. In addition, the first surface xa may cover the lower surface p2a and the side surfaces p2c of the second pixel defining layer PDL2 and may contact the lower surface p2a and the side surfaces p2c.

The second surface xb of the connection electrode CNE may be a surface opposite the first surface xa. The second surface xb may entirely contact the first light emitting layer EL1, the first cathode CE1, and the first auxiliary electrode AX1.

The first light emitting layer EL1 according to some embodiments may be located on and in contact with the first anode AE1 and the second pixel defining layer PDL2 in the portion overlapping the first emission area EA1. The first light emitting layer EL1 may completely cover the second pixel defining layer PDL2 and may contact the connection electrode CNE.

The first cathode CE1 according to some embodiments may entirely contact and cover the first light emitting layer EL1 in the portion overlapping the first emission area EA1. The first cathode CE1 may contact the connection electrode CNE and may be electrically connected to the bank layer BN through the connection electrode CNE.

The first auxiliary electrode AX1 according to some embodiments may entirely contact and cover the first cathode CE1 in the portion overlapping the first emission area EA1. The first auxiliary electrode AX1 may cover the first tips TIP1 of the third bank layer BN3 and the second tips TIP2 of the second pixel defining layer PDL2. The first auxiliary electrode AX1 may contact the connection electrode CNE and may be electrically connected to the bank layer BN through the connection electrode CNE.

The first inorganic layer TFE11 according to some embodiments may entirely cover the bank layer BN and the first light emitting element ED1 in the portion overlapping the first emission area EA1. The first inorganic layer TFE11 may cover an undercut portion formed between the side surfaces 2c of the second bank layer BN2 and the first tips TIP1 of the third bank layer BN3.

The first inorganic layer TFE11 may be spaced apart from the first bank layer BN1 in the third direction (Z-axis direction) with a cavity Cavity interposed between them in portions overlapping the first tips TIP1 and the second tips TIP2.

The first inorganic layer TFE11 may include a step according to the profile of a structure thereunder, and the step formed by the first inorganic layer TFE11 may be flattened by the second encapsulation layer TFE2. Some redundant descriptions may be omitted.

For ease of description, the light emitting element layer EML overlapping the first emission area EA1 is illustrated and described. However, the structure and characteristics of the light emitting element layer EML overlapping the second emission area EA2 and the third emission area EA3 may be the same as the structure and characteristics of the light emitting element layer EML overlapping the first emission area EA1.

To sum up with reference to FIGS. 5 through 7, because the display panel 410 according to some embodiments includes the first pixel defining layer PDL1 and the second pixel defining layer PDL2 including a step, a deposition area of the first light emitting element ED1 can be controlled in the manufacturing process. Accordingly, an ultra-high-resolution light emitting element ED can be formed.

In addition, the display panel 410 according to some embodiments includes a connection electrode CNE which contacts and covers a step formed by the third bank layer BN3 and the pixel defining layer PDL. Therefore, a contact area between the first auxiliary electrode AX1 and the third bank layer BN3 can be relatively increased. Accordingly, the display panel 410 can solve a contact failure between the first cathode CE1, the first auxiliary electrode AX1, and the third bank layer BN3.

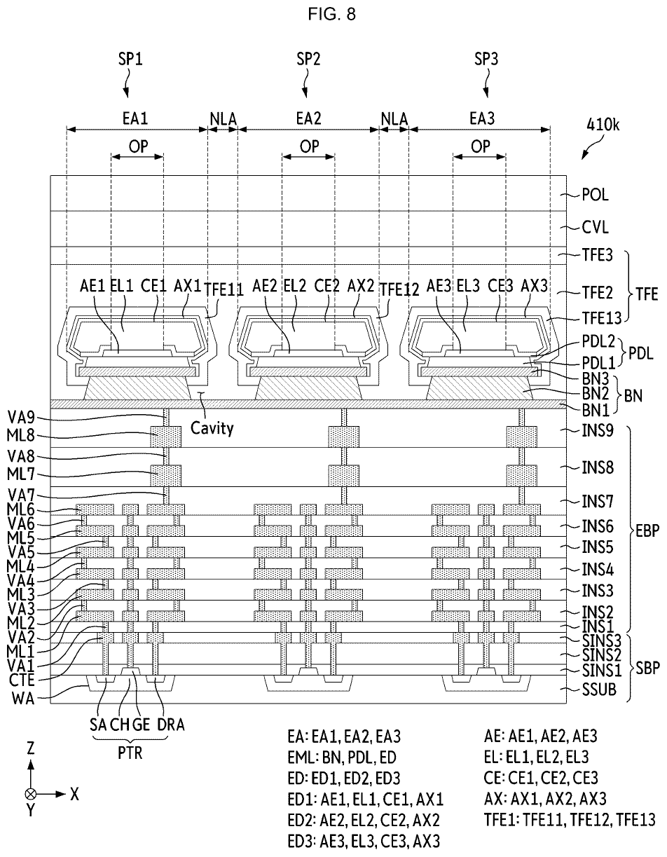

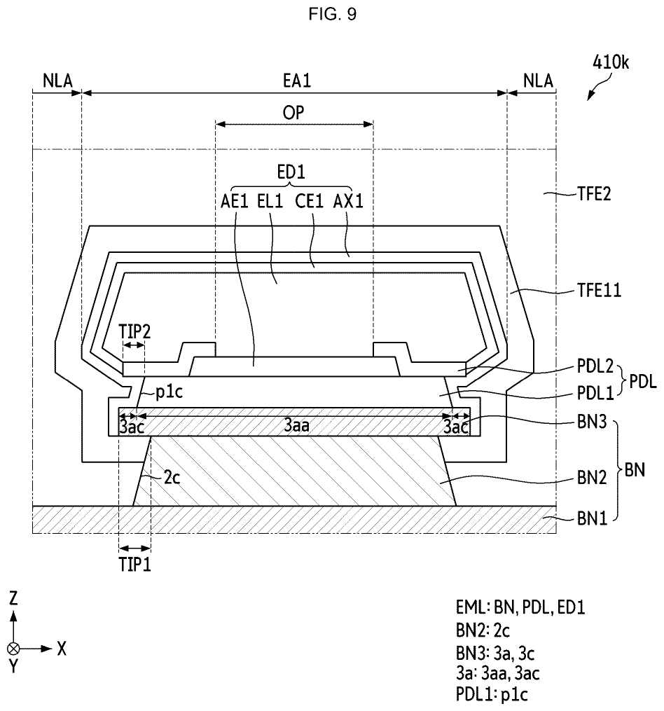

FIG. 8 is a schematic cross-sectional view of a display panel 410k according to some embodiments, taken along the line X1-X1′ of FIG. 4. FIG. 9 is an enlarged cross-sectional view of a light emitting element layer EML overlapping a first emission area EA1 in FIG. 8.

Referring to FIGS. 8 and 9, the display panel 410k according to some embodiments may be different from the display panel 410 in that auxiliary electrodes AX directly contact a pixel defining layer PDL and a bank layer BN. A description of commonalities between the display panel 410 and the display panel 410k will be omitted, and some differences will be described in more detail below.

The light emitting element layer EML of the display panel 410k may include the bank layer BN, the pixel defining layer PDL, and a first light emitting element ED1 in a portion overlapping the first emission area EA1.

A third bank layer BN3 of the display panel 410k may include first tips TIP1 that protrude more than side surfaces 2c of a second bank layer BN2 toward a non-emission area NLA. The first tips TIP1 of the third bank layer BN3 may be covered by a first auxiliary electrode AX1 and may contact the first auxiliary electrode AX1. The first auxiliary electrode AX1 and the third bank layer BN3 may be electrically connected.

According to some embodiments, the third bank layer BN3 may include an upper surface 3a that faces a first pixel defining layer PDL1. The upper surface 3a of the third bank layer BN3 may include a first portion 3aa and a second portion 3ac depending on a structure that it contacts. The first portion 3aa may be a portion that contacts the first pixel defining layer PDL1, and the second portion 3ac may be a portion that contacts the first auxiliary electrode AX1.

The first pixel defining layer PDL1 included in the display panel 410k may be located on and in contact with the third bank layer BN3 in the portion overlapping the first emission area EA1. The first pixel defining layer PDL1 may include side surfaces p1c that face the non-emission area NLA. The side surfaces pic of the first pixel defining layer PDL1 may be entirely covered by the first auxiliary electrode AX1 and may entirely contact the first auxiliary electrode AX1.

A second pixel defining layer PDL2 included in the display panel 410k may be located on and in contact with the first pixel defining layer PDL1 in the portion overlapping the first emission area EA1. The second pixel defining layer PDL2 may include second tips TIP2 that protrude more than the side surfaces p1c of the first pixel defining layer PDL1 toward the non-emission area NLA. An undercut may be formed between the second tips TIP2 of the second pixel defining layer PDL2 and the side surfaces p1c of the first pixel defining layer PDL1.

In the display panel 410k, because the pixel defining layer PDL includes a step, a light emitting layer EL, a cathode CE, and an auxiliary electrode AX spaced apart from each other can be formed without using a fine metal mask. Redundant descriptions will be omitted.

The second tips TIP2 of the second pixel defining layer PDL2 included in the display panel 410k may contact a first light emitting layer EL1, a first cathode CE1 and the first auxiliary electrode AX1 and may be covered by the first light emitting layer EL1, the first cathode CE1 and the first auxiliary electrode AX1.

The first auxiliary electrode AX1 included in the display panel 410k may contact the third bank layer BN3, the first pixel defining layer PDL1, and the second pixel defining layer PDL2. For example, the first auxiliary electrode AX1 may cover them along a profile formed by the second tips TIP2 of the second pixel defining layer PDL2, the side surfaces p1c of the first pixel defining layer PDL1 and the first tips TIP1 of the third bank layer BN3 and may contact the first tips TIP1 and the second tips TIP2. Other redundant descriptions will be omitted.

For ease of description, an enlarged structure of the light emitting element layer EML overlapping the first emission area EA1 included in the display panel 410k is illustrated and described. However, the structure and characteristics of the light emitting element layer EML overlapping a second emission area EA2 and a third emission area EA3 may be the same as the structure and characteristics of the light emitting element layer EML overlapping the first emission area EA1.

To sum up with reference to FIGS. 8 and 9, because the display panel 410k includes the third bank layer BN3 and the pixel defining layer PDL including a step, a deposition area of the first light emitting element ED1 can be controlled in a manufacturing process. Accordingly, an ultra-high-resolution light emitting element ED can be formed.

In addition, the display panel 410k includes the first auxiliary electrode AX1 which contacts and covers a step formed by the third bank layer BN3 and the pixel defining layer PDL. Therefore, a contact area between the first auxiliary electrode AX1 and the third bank layer BN3 can be relatively increased. Accordingly, the display panel 410k can solve a contact failure between the first cathode CE1, the first auxiliary electrode AX1, and the third bank layer BN3.

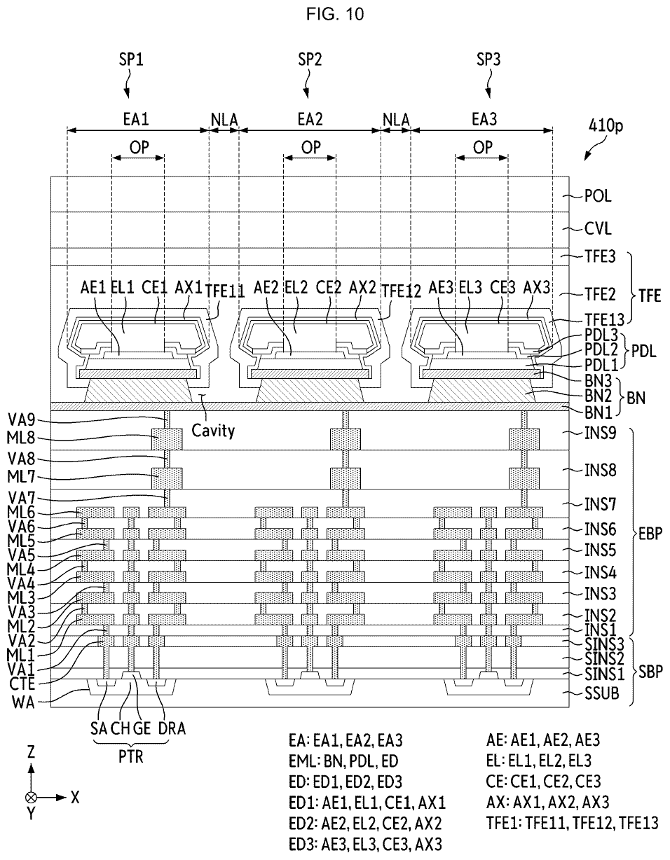

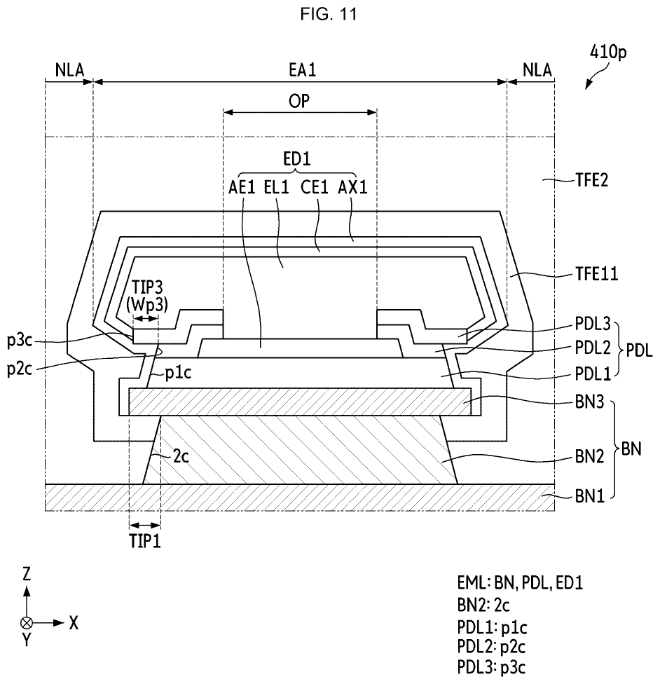

FIG. 10 is a schematic cross-sectional view of a display panel 410p according to some embodiments, taken along the line X1-X1′ of FIG. 4. FIG. 11 is an enlarged cross-sectional view of a light emitting element layer EML overlapping a first emission area EA1 in FIG. 10.

Referring to FIGS. 10 and 11, the display panel 410p may be different from the display panel 410 in that a pixel defining layer PDL includes a first pixel defining layer PDL1, a second pixel defining layer PDL2, and a third pixel defining layer PDL3. A description of commonalities between the display panel 410 and the display panel 410p will be omitted, and differences will be described below.

The light emitting element layer EML of the display panel 410p may include a bank layer BN, the pixel defining layer PDL, and a first light emitting element ED1 in a portion overlapping the first emission area EA1.

A third bank layer BN3 of the display panel 410p may include first tips TIP1 that protrude more than side surfaces 2c of a second bank layer BN2 toward a non-emission area NLA in the portion overlapping the first emission area EA1. In addition, the first pixel defining layer PDL1 of the display panel 410p may be located on and in contact with the third bank layer BN3 in the portion overlapping the first emission area EA1. In addition, the second pixel defining layer PDL2 of the display panel 410p may be located on the first pixel defining layer PDL1 and a first anode AE1 in the portion overlapping the first emission area EA1. The second pixel defining layer PDL2 may expose an opening OP and cover edges of the first anode AE1.

According to some embodiments, the second pixel defining layer PDL2 may include the same material as the first pixel defining layer PDL1.

According to some embodiments, the second pixel defining layer PDL2 may include side surfaces p2c that face the non-emission area NLA. The side surfaces p2c of the second pixel defining layer PDL2 may be located on the same straight line as side surfaces p1c of the first pixel defining layer PDL1. In other words, the side surfaces p1c of the first pixel defining layer PDL1 and the side surfaces p2c of the second pixel defining layer PDL2 may extend along the same straight line.

The third pixel defining layer PDL3 of the display panel 410p may be located on the second pixel defining layer PDL2 in the portion overlapping the first emission area EA1. The third pixel defining layer PDL3 may surround the opening OP and expose the first anode AE1.

The third pixel defining layer PDL3 may include an inorganic insulating material. For example, the third pixel defining layer PDL3 may include any one of silicon oxide, silicon nitride, and silicon oxynitride. However, the third pixel defining layer PDL3 may include a different material from the first pixel defining layer PDL1 and the second pixel defining layer PDL2. For example, when the first pixel defining layer PDL1 and the second pixel defining layer PDL2 include silicon nitride, the third pixel defining layer PDL3 may include silicon oxide.

The third pixel defining layer PDL3 may include side surfaces p3c that face the non-emission area NLA. The side surfaces p3c of the third pixel defining layer PDL3 may protrude more than the side surfaces p2c of the second pixel defining layer PDL2 toward the non-emission area NLA. Accordingly, the third pixel defining layer PDL3 may have third tips TIP3 that protrude more than the side surfaces p2c of the second pixel defining layer PDL2 toward the non-emission area NLA. An undercut may be formed between the third tips TIP3 of the third pixel defining layer PDL3 and the side surfaces p2c of the second pixel defining layer PDL2.

The third tips TIP3 of the third pixel defining layer PDL3 may overlap the first tips TIP1 of the third bank layer BN3 in the third direction (Z-axis direction).

According to some embodiments, a width Wp3 of the third tips TIP3 of the third pixel defining layer PDL3 may have a value of 0.01 to 0.5 micrometers.

In the display panel 410p, because the pixel defining layer PDL includes a step, a light emitting layer EL, a cathode CE, and an auxiliary electrode AX spaced apart from each other can be formed without using a fine metal mask. Some redundant or repetitive descriptions may be omitted.

A first light emitting layer EL1 included in the display panel 410p may cover the first anode AE1 and the third pixel defining layer PDL3 and may contact the third tips TIP3 of the third pixel defining layer PDL3. In addition, a first cathode CE1 included in the display panel 410p may entirely contact and cover the first light emitting layer EL1 and may contact the third tips TIP3 of the third pixel defining layer PDL3.

A first auxiliary electrode AX1 included in the display panel 410p may contact the third bank layer BN3, the first pixel defining layer PDL1, the second pixel defining layer PDL2, and the third pixel defining layer PDL3. For example, the first auxiliary electrode AX1 may cover them along a profile formed by the third tips TIP3 of the third pixel defining layer PDL3, the side surfaces p1c of the first pixel defining layer PDL1, the side surfaces p2c of the second pixel defining layer PDL2 and the first tips TIP1 of the third bank layer BN3 and may contact the first tips TIP1 and the third tips TIP3. Some redundant or repetitive descriptions may be omitted.

For ease of description, an enlarged structure of the light emitting element layer EML overlapping the first emission area EA1 included in the display panel 410p is illustrated and described. However, the structure and characteristics of the light emitting element layer EML overlapping a second emission area EA2 and a third emission area EA3 may be the same as the structure and characteristics of the light emitting element layer EML overlapping the first emission area EA1.

To sum up with reference to FIGS. 10 and 11, because the display panel 410p includes the third bank layer BN3 and the pixel defining layer PDL including a step, a deposition area of the first light emitting element ED1 can be controlled in a manufacturing process. Accordingly, an ultra-high-resolution light emitting element ED can be formed.

In addition, the display panel 410p includes the first auxiliary electrode AX1 which contacts and covers a step formed by the third bank layer BN3 and the pixel defining layer PDL. Therefore, a contact area between the first auxiliary electrode AX1 and the third bank layer BN3 can be relatively increased. Accordingly, the display panel 410p can solve a contact failure between the first cathode CE1, the first auxiliary electrode AX1, and the third bank layer BN3.

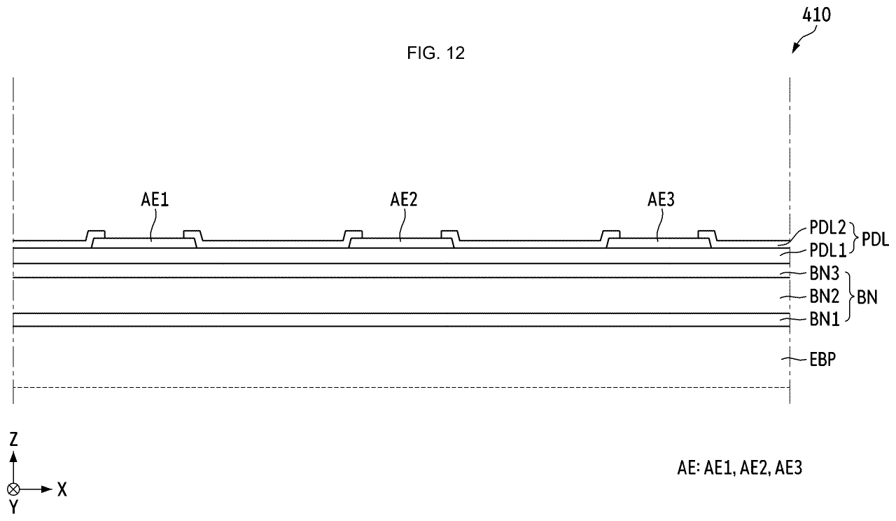

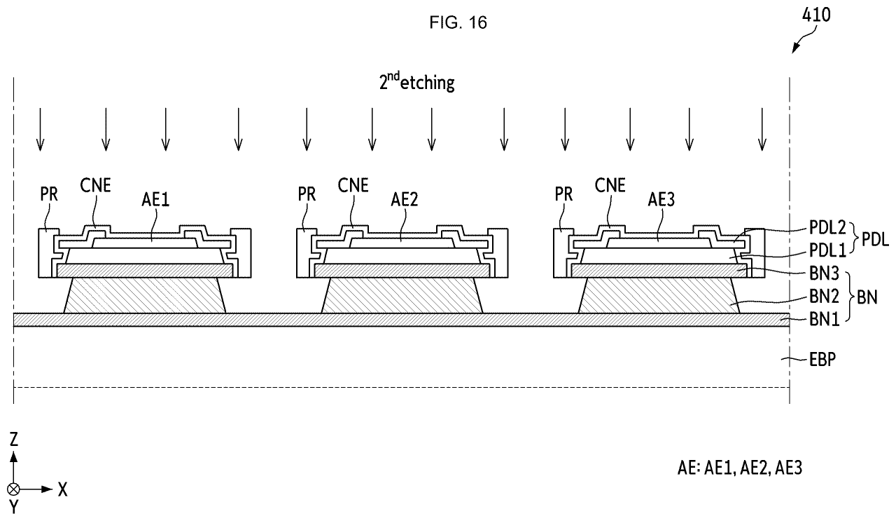

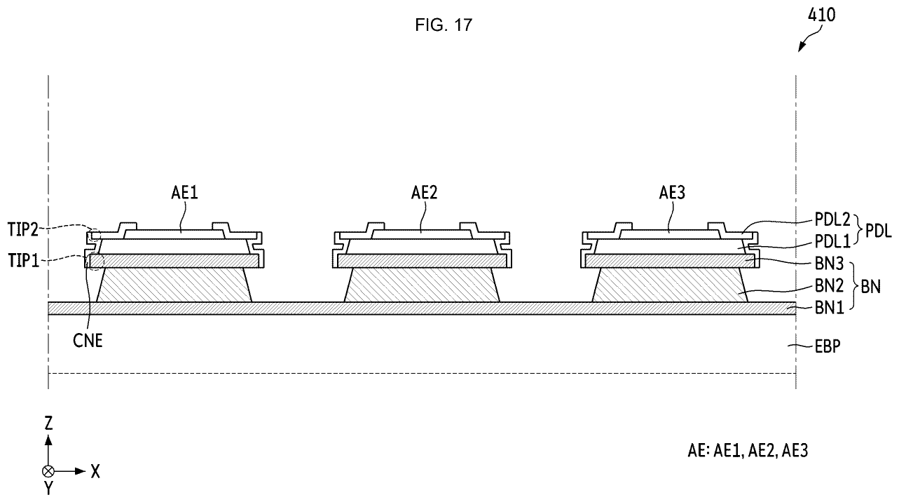

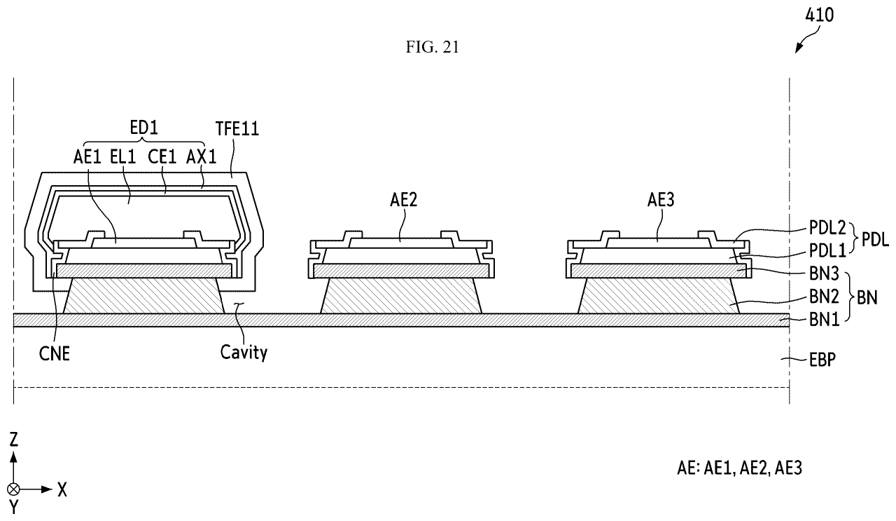

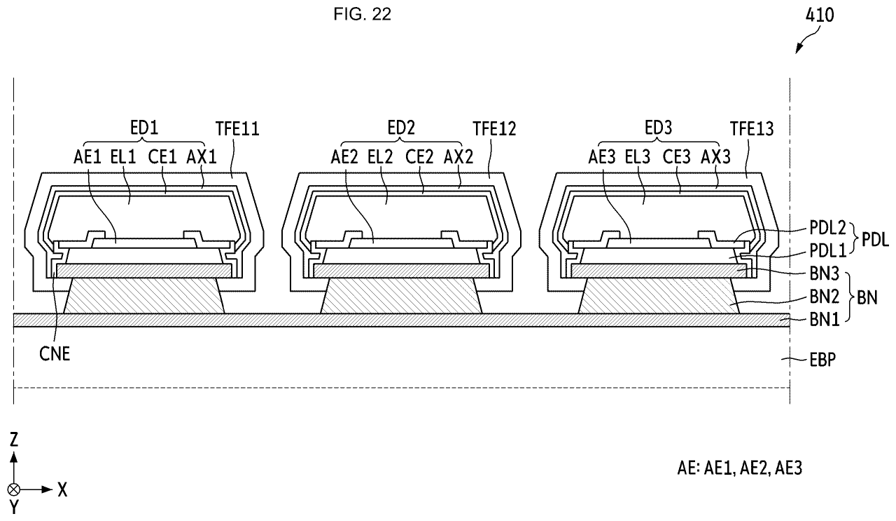

FIGS. 12 through 22 are cross-sectional views sequentially illustrating a process of manufacturing a light emitting element layer of a display panel 410 according to some embodiments. The process of manufacturing the light emitting element layer will now be described in the order of formation of each layer.

Referring to FIG. 12, a bank layer BN, anodes AE, and a pixel defining layer PDL are formed on a light emitting element backplane EBP. The bank layer BN may include a first bank layer BN1, a second bank layer BN2, and a third bank layer BN3. The pixel defining layer PDL may include a first pixel defining layer PDL1 and a second pixel defining layer PDL2. The structure of the light emitting element backplane EBP is the same as that described above with reference to FIG. 5. Redundant descriptions will be omitted.

The first bank layer BN1 may cover the entire surface of the light emitting element backplane EBP, the second bank layer BN2 may cover the entire surface of the first bank layer BN1, and the third bank layer BN3 may cover the entire surface of the second bank layer BN2. The second bank layer BN2 and the third bank layer BN3 may include different materials, and the third bank layer BN3 may include a material having higher etch resistance than that of the second bank layer BN2 in the same etching process. Some redundant or repetitive descriptions may be omitted.

The first pixel defining layer PDL1 may be formed on the entire surface of the third bank layer BN3, and a plurality of anodes AE may be placed on the first pixel defining layer PDL1. The anodes AE may include a first anode AE1, a second anode AE2, and a third anode AE3. The first anode AE1, the second anode AE2, and the third anode AE3 may be spaced apart from each other.

The second pixel defining layer PDL2 may partially expose the anodes AE and may surround edges of the anodes AE. The second pixel defining layer PDL2 may include a different material from the first pixel defining layer PDL1. Redundant descriptions will be omitted.

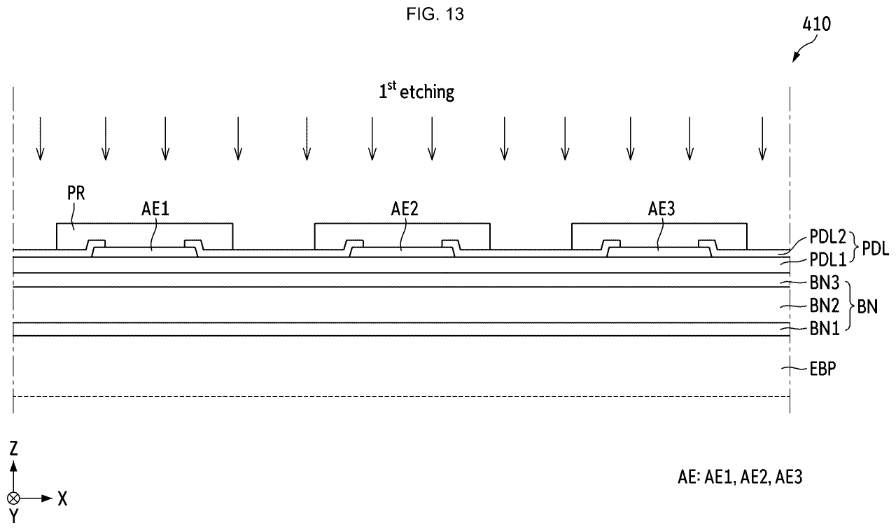

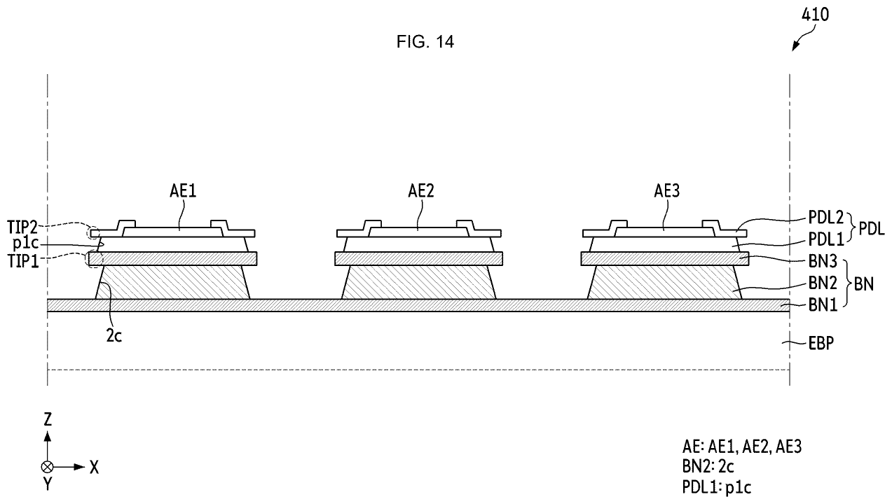

Next, referring to FIGS. 13 and 14, a plurality of photoresists PR are formed on the anodes AE and the second pixel defining layer PDL2. The photoresists PR may completely cover the first anode AE1, the second anode AE2, and the third anode AE3, respectively.

Next, a first etching process is performed using the photoresists PR as a mask. For example, in the first etching process, a dry etching process and a wet etching process may be alternately performed, but embodiments are not limited thereto.

In the current process, portions of the pixel defining layer PDL, the second bank layer BN2, and the third bank layer BN3 which are not overlapped by the photoresists PR may be removed. In the current process, the second bank layer BN2 and the third bank layer BN3 including different metal materials may have different etch selectivities. For example, in the same etching process, the third bank layer BN3 may have higher etch resistance than the second bank layer BN2. In other words, in the same etching process, the second bank layer BN2 may include a material having a higher etch rate than that of the third bank layer BN3. Therefore, the third bank layer BN3 may include first tips TIP1 that protrude more than side surfaces 2c of the second bank layer BN2 in the first direction (X-axis direction).

In addition, in the current process, the first pixel defining layer PDL1 and the second pixel defining layer PDL2 including different inorganic materials may have different etch selectivities. For example, in the same etching process, the second pixel defining layer PDL2 may have higher etch resistance than the first pixel defining layer PDL1. In other words, in the same etching process, the first pixel defining layer PDL1 may include a material having a higher etch rate than that of the second pixel defining layer PDL2. Therefore, the second pixel defining layer PDL2 may include second tips TIP2 that protrude more than side surfaces p1c of the first pixel defining layer PDL1 in the first direction (X-axis direction).

Because the display panel 410 according to some embodiments includes the second bank layer BN2 and the third bank layer BN3 including different metal materials and the first pixel defining layer PDL1 and the second pixel defining layer PDL2 including different inorganic materials, the bank layer BN and the pixel defining layer PDL having an undercut shape can be formed in a single process. Accordingly, the display panel 410 according to some embodiments may have ease of manufacture.

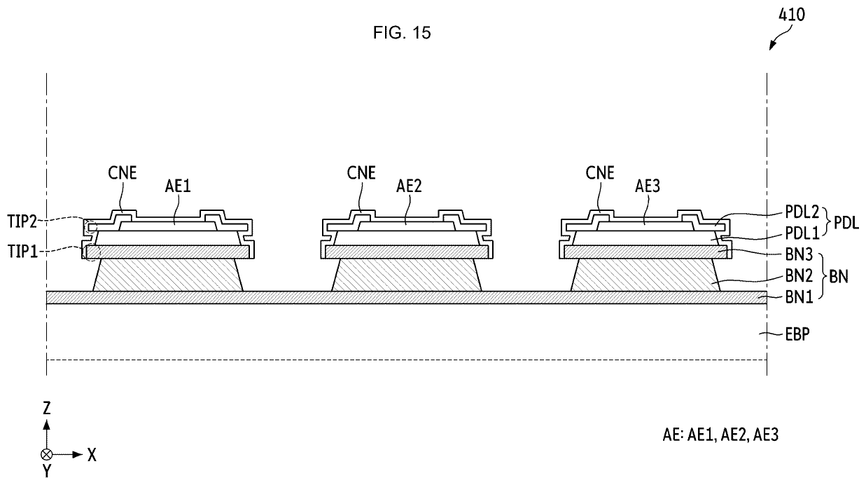

Next, referring to FIGS. 15 through 17, connection electrodes CNE are deposited on the pixel defining layer PDL. This process may be performed by a damage free sputter (DFS) facility. Therefore, damage to organic materials caused by plasma can be minimized or reduced.

In the current process, the connection electrodes CNE may entirely cover the second pixel defining layer PDL2 and the anodes AE. In addition, the connection electrodes CNE may cover the first tips TIP1 of the third bank layer BN3, the first pixel defining layer PDL1, and the second tips TIP2 of the second pixel defining layer PDL2.

Next, a plurality of photoresists PR are formed on the connection electrodes CNE. The photoresists PR may cover edges of the connection electrodes CNE, thereby partially exposing the connection electrodes CNE. Next, a second etching process is performed using the photoresists PR as a mask. For example, the second etching process may be performed as a dry etching process.

In the current process, portions of the connection electrodes CNE which are not overlapped by the photoresists PR may be removed, thereby exposing the anodes AE and the second pixel defining layer PDL2.

In the current process, the connection electrodes CNE overlapping the photoresists PR may cover the first tips TIP1 of the third bank layer BN3 and the second tips TIP2 of the second pixel defining layer PDL2. The connection electrodes CNE covering the first tips TIP1 and the connection electrodes CNE covering the second tip TIP2 may be integrally formed.

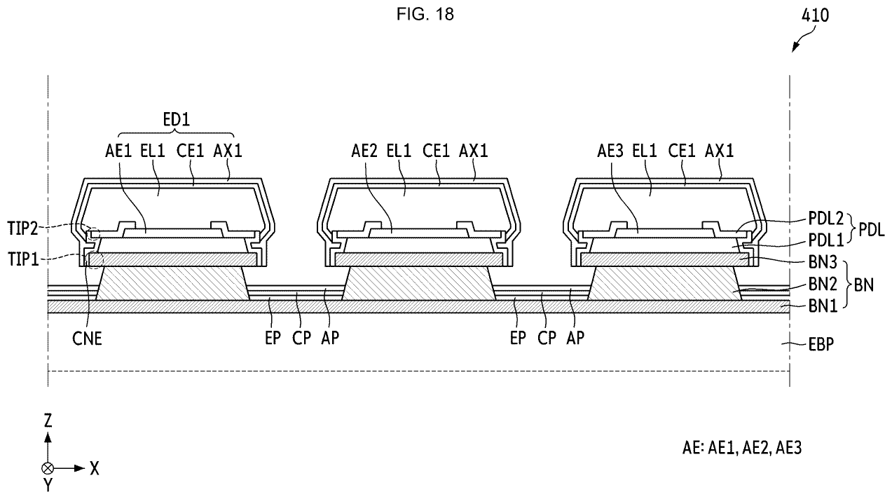

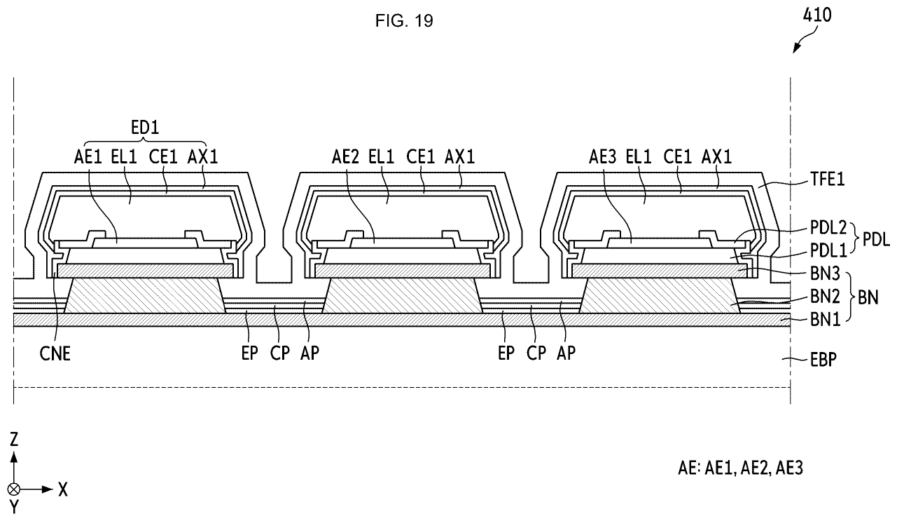

Next, referring to FIGS. 18 and 19, a first light emitting layer EL1, a first cathode CE1, and a first auxiliary electrode AX1 are deposited on the first anode AE1 to form a first light emitting element ED1.

In the current process, a process of forming the first light emitting layer EL1 may be performed through a thermal deposition process. As described above, because the display panel 410 includes the first pixel defining layer PDL1 and the second pixel defining layer PDL2 having a step, the process of forming the first light emitting layer EL1 can be performed without using a fine metal mask.

In the current process, a material that forms the first light emitting layer EL1 may be formed not only on the first anode AE1, but also on the second anode AE2, the third anode AE3, and the first bank layer BN1. In the current process, the material that forms the first light emitting layer EL1 formed on the first bank layer BN1 may be spaced apart from the material that forms the first light emitting layer EL1 formed on the anodes AE. The material that forms the first light emitting layer EL1 formed on the first bank layer BN1 may be formed in the form of an organic pattern EP as illustrated in the drawings.

Next, the first cathode CE1 is formed on the first light emitting layer EL1. The first cathode CE1 may contact a connection electrode CNE. In the current process, a process of forming the first cathode CE1 may be performed through any one of a thermal deposition process and a sputtering deposition process. As described above, because the display panel 410 includes the first pixel defining layer PDL1 and the second pixel defining layer PDL2 having a step, the process of forming the first cathode CE1 can be performed without using a fine metal mask.

In the current process, a material that forms the first cathode CE1 may be formed not only on the first anode AE1, but also on the second anode AE2, the third anode AE3, and the first bank layer BN1. In the current process, the material that forms the first cathode CE1 formed on the first bank layer BN1 may be spaced apart from the material that forms the first cathode CE1 formed on the anodes AE. The material that forms the first cathode CE1 formed on the first bank layer BN1 may be formed in the form of an electrode pattern CP as illustrated in the drawings.

Next, the first auxiliary electrode AX1 is formed on the first cathode CE1. The first auxiliary electrode AX1 may cover the first tips TIP1 and the second tips TIP2 and may contact the connection electrode CNE. In the current process, the first auxiliary electrode AX1 may be formed through a sputtering deposition process. As described above, because the display panel 410 includes the first pixel defining layer PDL1 and the second pixel defining layer PDL2 having a step, the process of forming the first auxiliary electrode AX1 can be performed without using a fine metal mask.

In the current process, a material that forms the first auxiliary electrode AX1 may be formed not only on the first anode AE1, but also on the second anode AE2, the third anode AE3, and the first bank layer BN1. In the current process, the material that forms the first auxiliary electrode AX1 formed on the first bank layer BN1 may be spaced apart from the material that forms the first auxiliary electrode AX1 formed on the anodes AE. The material that forms the first auxiliary electrode AX1 formed on the first bank layer BN1 may be formed in the form of an auxiliary electrode pattern AP as illustrated in the drawings.

Next, a first encapsulation layer TFE1 is formed on the first auxiliary electrode AX1. The first encapsulation layer TFE1 may entirely cover the first anode AE1, the second anode AE2, and the third anode AE3. In addition, the first encapsulation layer TFE1 may entirely cover the organic pattern EP, the electrode pattern CP, and the auxiliary electrode pattern AP.

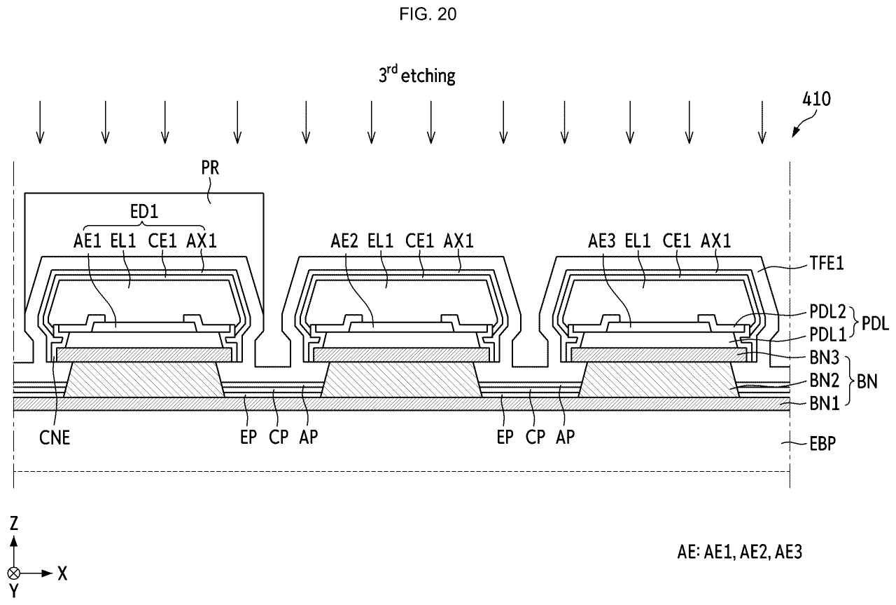

Next, referring to FIGS. 20 through 22, a photoresist PR is formed in a portion overlapping the first anode AE1 and an area around the first anode AE1, and a third etching process is performed using the photoresist PR as a mask.

In the current process, the material that forms the first light emitting layer EL1, the material that forms the first cathode CE1, the material that forms the first auxiliary electrode AX1, and a material that forms the first encapsulation layer TFE1 in a portion not overlapping the photoresist PR may all be removed at once. Through this process, the second anode AE2 and the third anode AE3 may be exposed again, and the organic pattern EP, the electrode pattern CP and the auxiliary electrode pattern AP located on the first bank layer BN1 may be removed. Accordingly, the first light emitting element ED1 and the first inorganic layer TFE11 illustrated in FIG. 5 may be formed.

In the current process, cavities Cavity may be formed between the first inorganic layer TFE11 and the first bank layer BN1 in the third direction (Z-axis direction). The cavities Cavity may be formed by the removal of the organic pattern EP, the electrode pattern CP, and the auxiliary electrode pattern AP.

Next, the same process is repeated to form a second light emitting layer EL2, a second cathode CE2, a second auxiliary electrode AX2, and the first encapsulation layer TFE1 on the second anode AE2. Accordingly, a second light emitting element ED2 and a second inorganic layer TFE12 are formed. In addition, a third light emitting layer EL3, a third cathode CE3, a third auxiliary electrode AX3, and the first encapsulation layer TFE1 are formed on the third anode AE3 to form a third light emitting element ED3 and a third inorganic layer TFE13. As a result, the light emitting element layer EML illustrated in FIG. 5 may be formed. Redundant descriptions will be omitted.

In a display device and a method of manufacturing the same according to some embodiments, light emitting elements spaced apart from each other may be formed without a separate etching process, and a contact area between an auxiliary electrode and a bank structure may be relatively increased.

However, the characteristics of embodiments according to the present disclosure are not restricted to the one set forth herein. The above and other characteristics of embodiments according to the present disclosure will become more apparent to one of daily skill in the art to which the present disclosure pertains by referencing the claims.

In concluding the detailed description, those skilled in the art will appreciate that many variations and modifications can be made to the disclosed embodiments without substantially departing from the principles of the present disclosure. Therefore, the disclosed embodiments of the invention are used in a generic and descriptive sense only and not for purposes of limitation.

The above description is an example of technical features of the disclosure, and those skilled in the art to which the disclosure pertains will be able to make various modifications and variations. Therefore, the embodiments according to the present disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The scope of embodiments according to the present disclosure should be interpreted by the following claims, and their equivalents, and it should be interpreted that all technical spirits within the equivalent scope are included in the scope of the disclosure.

What is claimed is:

1. A display device including:
a substrate including an emission area and a non-emission area;
a bank layer on the emission area of the substrate and including a first tip which protrudes in a direction toward the non-emission area;
a pixel defining layer on the bank layer and defining an opening; and
a light emitting element on the pixel defining layer and including a cathode and an auxiliary electrode,
wherein the pixel defining layer comprises a first pixel defining layer and a second pixel defining layer located on the first pixel defining layer and including a second tip which protrudes more than a side surface of the first pixel defining layer toward the non-emission area, and the auxiliary electrode covers the first tip of the bank layer and the second tip of the second pixel defining layer.

2. The display device of claim 1, wherein the side surface of the first pixel defining layer and the second tip of the second pixel defining layer form an undercut.

3. The display device of claim 2, wherein the first tip overlaps the second tip in a direction perpendicular to the substrate in a portion overlapping the emission area.

4. The display device of claim 3, wherein the first pixel defining layer and the second pixel defining layer comprise different materials.

5. The display device of claim 4, wherein a width of the second tip is in a range of 0.01 to 0.5 micrometers in a direction parallel to the substrate.

6. The display device of claim 1, including a connection electrode on the first tip of the bank layer and the second tip of the second pixel defining layer in the direction toward the non-emission area, wherein the connection electrode does not overlap the opening.

7. The display device of claim 6, wherein the connection electrode contacts and covers the first tip of the bank layer, the side surface of the first pixel defining layer, and the second tip of the second pixel defining layer.

8. The display device of claim 7, wherein the cathode and the auxiliary electrode contact the connection electrode and are electrically connected to the bank layer by the connection electrode.

9. The display device of claim 1, wherein the bank layer comprises a first bank layer, a second bank layer, and a third bank layer stacked sequentially, and the second bank layer and the third bank layer comprise different materials.

10. The display device of claim 9, wherein the third bank layer comprises the first tip, and an undercut is formed between a side surface of the second bank layer, which faces the non-emission area, and the first tip of the third bank layer.

11. The display device of claim 10, wherein the second bank layer comprises aluminum, and the third bank layer comprises titanium.

12. The display device of claim 9, further including:
a first encapsulation layer on the light emitting element and including an inorganic material; and
a second encapsulation layer on the first encapsulation layer and including an organic material,
wherein the side surface of the second bank layer comprises a first portion that contacts the first encapsulation layer and a second portion that contacts the second encapsulation layer.

13. The display device of claim 12, wherein a cavity is formed between the first bank layer and the first encapsulation layer in the direction perpendicular to the substrate in a portion overlapping the emission area and is filled with the second encapsulation layer.

14. The display device of claim 1, wherein the auxiliary electrode contacts the first tip of the bank layer, the side surface of the first pixel defining layer, and the second tip of the second pixel defining layer.

15. The display device of claim 1, wherein the light emitting element further comprises a light emitting layer located between the second pixel defining layer and the cathode, and the light emitting layer entirely covers the second pixel defining layer.

16. The display device of claim 1, wherein the bank layer and the pixel defining layer overlap the emission area and do not overlap the non-emission area.

17. A method of manufacturing a display device, the method including:
forming a bank layer on an emission area of a substrate and then forming a pixel defining layer and an anode on the bank layer;
forming a bank layer including a first tip which protrudes in a direction parallel to the substrate and a pixel defining layer including a second tip which protrudes in a direction parallel to the substrate by removing portions of the bank layer and the pixel defining layer which do not overlap the anode; and
forming a light emitting layer on the anode, forming a cathode on the light emitting layer, and forming an auxiliary electrode, which covers the first tip and the second tip, on the cathode,
wherein the light emitting layer is formed by a photo pattern process in the forming of the light emitting layer, and the pixel defining layer comprises a first pixel defining layer and a second pixel defining layer including the second tip which protrudes more than a side surface of the first pixel defining layer.

18. The method of claim 17, wherein in the forming of the first tip, the bank layer comprises a first bank layer and a second bank layer having higher etch resistance than the first bank layer.

19. The method of claim 18, wherein in the forming of the second tip, the second pixel defining layer has higher etch resistance than the first pixel defining layer.

20. An electronic device including:
at least one display device including a substrate having an emission area and a non-emission area;
a display device housing in which the at least one display device is housed; and
an optical member enlarging a display image of the at least one display device or converting an optical path,
wherein the at least one display device comprises:
a bank layer on the emission area of the substrate and including a first tip which protrudes in a direction toward the non-emission area;
a pixel defining layer on the bank layer and defining an opening; and
a light emitting element on the pixel defining layer and including a cathode and an auxiliary electrode,
wherein the pixel defining layer comprises a first pixel defining layer and a second pixel defining layer on the first pixel defining layer and including a second tip which protrudes more than a side surface of the first pixel defining layer toward the non-emission area, and the auxiliary electrode covers the first tip of the bank layer and the second tip of the second pixel defining layer.
